(19) United States
(12) Patent Application Publication
(10) Pub. No.: US 2026/0143779 A1
(43) Pub. Date: May 21, 2026

(54) METHODS FOR FORMING TRANSISTORS

(71) Applicant: Taiwan Semiconductor Manufacturing Company, Ltd., Hsinchu (TW)

(72) Inventors: Yu-Chih Chen, Taoyuan (TW); Fu-Hsiung Yang, Zhongli (TW); Szu-Hsien Liu, Zhubei (TW); Fei-Yun Chen, Hsinchu (TW)

(21) Appl. No.: 18/950,566

(22) Filed: Nov. 18, 2024

(51) Int. Cl. H01L 29/423; H01L 21/28; H01L 29/66

(52) U.S. Cl. CPC H10D 64/516; H10D 64/01332; H10D 64/017

(57) ABSTRACT

The gate dielectric layer of a transistor includes a central region and one or more edge regions. The thickness of the central region is less than the thickness of the plurality of edge regions. This increases the corner oxide thickness and reduces the double hump phenomenon, improving performance without needing an extra mask.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view showing a first example embodiment of a planar transistor, in accordance with some embodiments of the present disclosure. FIG. 1B is a Y-axis cross-sectional view along line B-B of FIG. 1A. FIG. 1C is an X-axis cross-sectional view along line C-C of FIG. 1A.

FIG. 1D is a larger plan view showing the planar transistor adjacent a logic area containing a FinFET transistor.

FIG. 2A and FIG. 2B together form a flow chart illustrating a method for concurrently forming the planar transistor and the FinFET transistor of FIG. 1D, in accordance with some embodiments. Various steps of this method are shown in FIGS. 3A-15B.

FIG. 3A is a plan view of the substrate after forming one or more isolation regions to define two active regions. FIG. 3B is a Y-axis cross-sectional view along line A-A of FIG. 3A. FIG. 3C is an X-axis cross-sectional view along line B-B of FIG. 3A.

FIG. 4A is a Y-axis cross-sectional view along line A-A of FIG. 3A, after formation of a first gate dielectric sublayer. FIG. 4B is an X-axis cross-sectional view along line B-B of FIG. 3A.

FIG. 5A is a Y-axis cross-sectional view along line A-A of FIG. 3A, after formation of a second gate dielectric sublayer. FIG. 5B is an X-axis cross-sectional view along line B-B of FIG. 3A.

FIG. 6A is a Y-axis cross-sectional view along line A-A of FIG. 3A, after etching trenches in one direction and formation of a dummy gate. FIG. 6B is an X-axis cross-sectional view along line B-B of FIG. 3A.

FIG. 7A is a Y-axis cross-sectional view along line A-A of FIG. 3A, after forming an etch stop layer and forming a first interlayer dielectric layer. FIG. 7B is an X-axis cross-sectional view along line B-B of FIG. 3A.

FIG. 8A is a Y-axis cross-sectional view along line A-A of FIG. 3A, after removal of the dummy gate. FIG. 8B is an X-axis cross-sectional view along line B-B of FIG. 3A. FIG. 8C is an X-axis cross-sectional view along line D-D of FIG. 1D, showing both active regions.

FIG. 9A is a Y-axis cross-sectional view along line A-A of FIG. 3A, after forming and patterning a photoresist layer that exposes a central region of the second gate dielectric sublayer. FIG. 9B is an X-axis cross-sectional view along line B-B of FIG. 3A. FIG. 9C is an X-axis cross-sectional view along line D-D of FIG. 1D, showing both active regions.

FIG. 10A is a Y-axis cross-sectional view along line A-A of FIG. 3A, after forming a recess in the central region of the second gate dielectric sublayer. FIG. 10B is an X-axis cross-sectional view along line B-B of FIG. 3A.

FIG. 11A is a Y-axis cross-sectional view along line A-A of FIG. 3A, after removal of the patterned photoresist layer. FIG. 11B is an X-axis cross-sectional view along line B-B of FIG. 3A. FIG. 11C is an X-axis cross-sectional view along line D-D of FIG. 1D, showing both active regions.

FIG. 12A is a Y-axis cross-sectional view along line A-A of FIG. 3A, after formation of the gate electrode and a gate protective layer. FIG. 12B is an X-axis cross-sectional view along line B-B of FIG. 3A.

FIG. 13A is a Y-axis cross-sectional view along line A-A of FIG. 3A, after forming a first insulating layer over the substrate. FIG. 13B is an X-axis cross-sectional view along line B-B of FIG. 3A.

FIG. 14A is a Y-axis cross-sectional view along line A-A of FIG. 3A, after forming at least one source/drain via and at least one gate via. FIG. 14B is an X-axis cross-sectional view along line B-B of FIG. 3A.

FIG. 15A is a Y-axis cross-sectional view along line A-A of FIG. 3A, after formation of source/drain electrodes. FIG. 15B is an X-axis cross-sectional view along line B-B of FIG. 3A.

FIG. 16 is a perspective view of the substrate after a second insulating layer has been applied over the first insulating layer, and pads are formed in the second insulating layer to form a source terminal, a drain terminal, and a gate terminal, to form the transistor.

FIG. 17 is a plan view of the substrate showing a first active region with a planar transistor and a second active region (or logic area) containing multiple FinFETs.

FIG. 18 is a magnified plan view illustrating a design scheme for resolving issues related to PR descum, rounding, and peeling in order to enlarge the process window.

FIG. 19 is a combined plan view and cross-sectional view illustrating the design scheme of FIG. 18.

FIGS. 20A-20C are plan views illustrating the design scheme applied to extended-space structures with different dimensions.

FIGS. 20D-20E are plan views illustrating the design scheme applied to square-type structures with different dimensions.

FIGS. 20F-20H are plan views illustrating the design scheme applied to H-type structures with different dimensions.

FIGS. 20I-20K are plan views illustrating the design scheme applied to special-type structures with different shapes.

FIG. 21 is a graph of current vs. voltage for a planar transistor having the structure of FIGS. 1A-1C. No double hump is seen.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to various methods and structures which are useful in improving the performance of transistors.

Gate oxide layers have a corner thinning problem which occurs because the corners cannot provide enough silicon atoms during oxidation. As a result, there is only a slight growth of oxide at the edges of the silicon surface which form “corners” adjacent the semiconducting channel through which current flows. Thus, the gate oxide layer is not uniformly thick. An undesirable side effect of this structure is a bimodal “double hump” in the drain current versus gate voltage (Id-Vg) curve when a back bias voltage (Vb) is applied. This occurs because the channel device threshold voltage (Vt1) is greater than the corner device threshold voltage (Vt2). This reduces device performance. In the present disclosure, a specified gate dielectric layer structure is used to reduce this double hump effect.

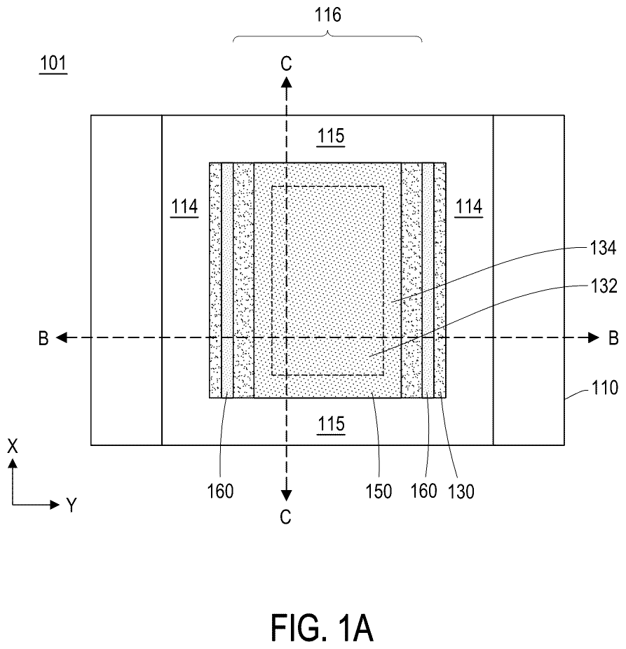

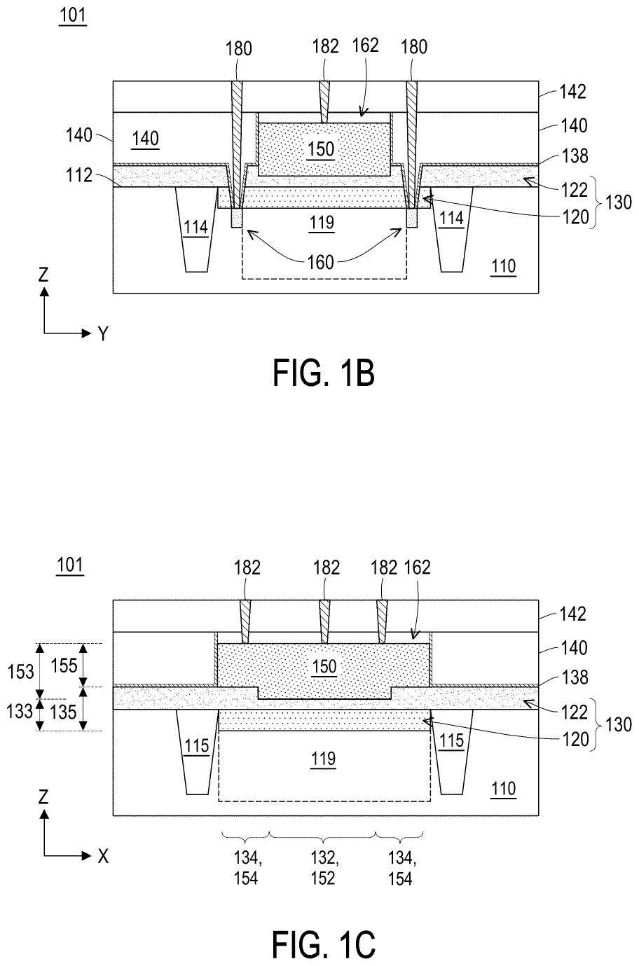

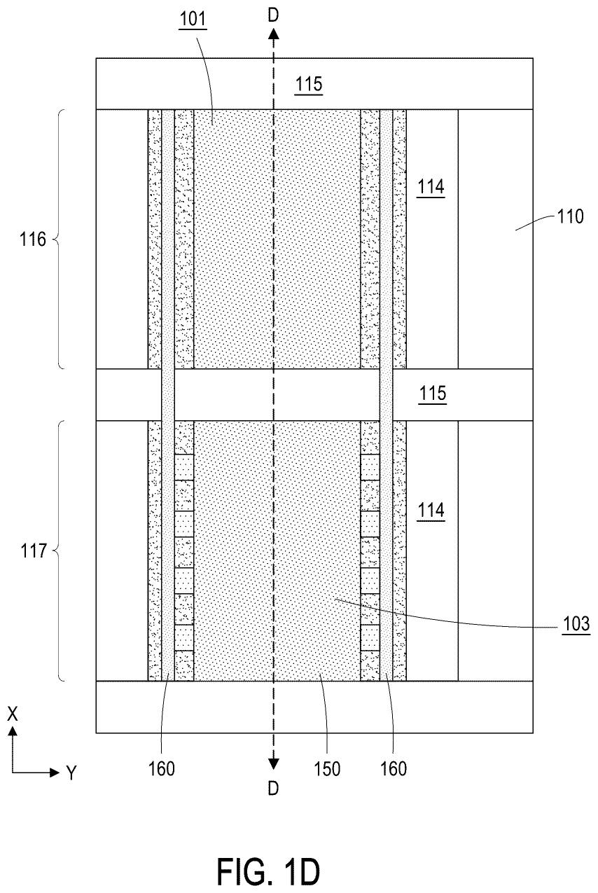

FIG. 1A is a plan view showing a first example embodiment of a transistor structure 101, in accordance with some embodiments of the present disclosure, and illustrating some features. FIG. 1B is a Y-axis cross-sectional view along line B-B of FIG. 1A. FIG. 1C is an X-axis cross-sectional view along line C-C of FIG. 1A.

Referring to the figures together, the transistor 101 is formed on a substrate 110. Two isolation regions 114 are present extending along the X-axis, and two isolation regions 115 are present extending along the Y-axis. These isolation regions may be, for example, shallow trench isolation (STI) regions (as shown in FIGS. 1A-1D) or deep trench isolation (DTI) regions. The area between them is defined as a first active region 116. It is noted that the active region is surrounded on all sides by the isolation regions 114, 115. In addition, the isolation regions directly contact each other, and they could also be considered as one isolation region if desired. Also visible in FIG. 1A are a gate dielectric layer 130, a gate electrode 150, and source/drain (S/D) electrodes 160 located within the first active region. In this regard, source/drain may refer to a source or a drain, individually or collectively, dependent upon the context.

As better seen in FIG. 1B and FIG. 1C, a semiconducting channel 119 is present between the isolation regions 114, 115. A first gate dielectric sublayer 120 is present, illustrated here as a layer below an upper surface 112 of the substrate 110. A second gate dielectric sublayer 122 is located over the first gate dielectric sublayer 120. As illustrated here, the second gate dielectric sublayer also extends over the isolation regions 114, 115. Together, the two gate dielectric sublayers 120, 122 form a gate dielectric layer 130. The gate electrode 150 is located upon the gate dielectric layer 130. A gate protective layer 162 is located upon the gate electrode 150. An etch stop layer 138 is present upon the gate dielectric layer 130 and the sides of the gate electrode 150. A first interlayer dielectric (ILD) layer 140 is located over the gate dielectric layer 130 that rises to the height of the gate protective layer. A second ILD layer 142 (also referred to herein as a first insulating layer) covers the gate electrode 150 and the first ILD layer 140.

In FIG. 1B, the source/drain (S/D) electrodes 160 are spaced apart from each other on opposite sides of the active region 116. The gate dielectric layer 130 and the gate electrode 150 are located between them, above the semiconducting channel 119. S/D vias 180 extend through the second ILD layer 142 and the first ILD layer 140 down to the S/D electrodes 160. One or more gate vias 182 extend through the second ILD layer 142 and the gate protective layer 162 to the gate electrode 150.

As seen in FIG. 1A and FIG. 1C, the second gate dielectric layer 122 and the gate dielectric layer 130 can be described as having a central region 132 and one or more edge regions 134. In the plan view of FIG. 1A, there may be considered to be only one edge region, but two edge regions in the cross-sectional view of FIG. 1C. The central region can be described as having a recess in which the gate electrode 150 rests. As a result, the thickness 133 of the central region 132 is less than the thickness 135 of the edge regions 134. The gate electrode 150 could also be described as having a central region 152 and one or more edge regions 154. The thickness 153 of the central region 152 is greater than the thickness 155 of the edge regions 154.

FIG. 1D is a larger plan view showing a substrate 110 having a planar transistor 101 in a first active region 116 and adjacent a second active region 117. The second active region can be, for example, a logic area containing a FinFET transistor 103. The two active regions are separated by an isolation region 115. They are oriented so that their S/D electrodes 160 and gate electrodes 150 are each in the same axis.

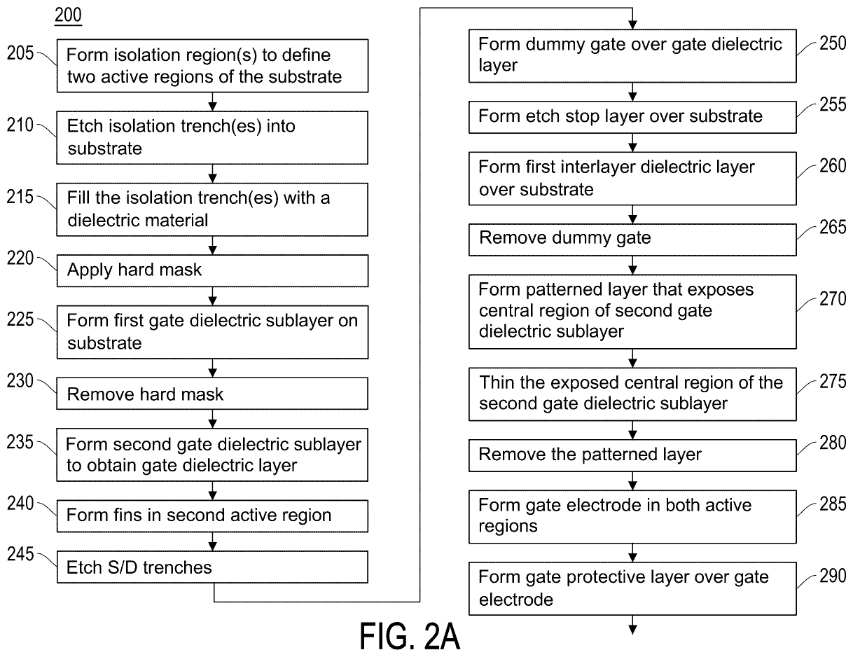

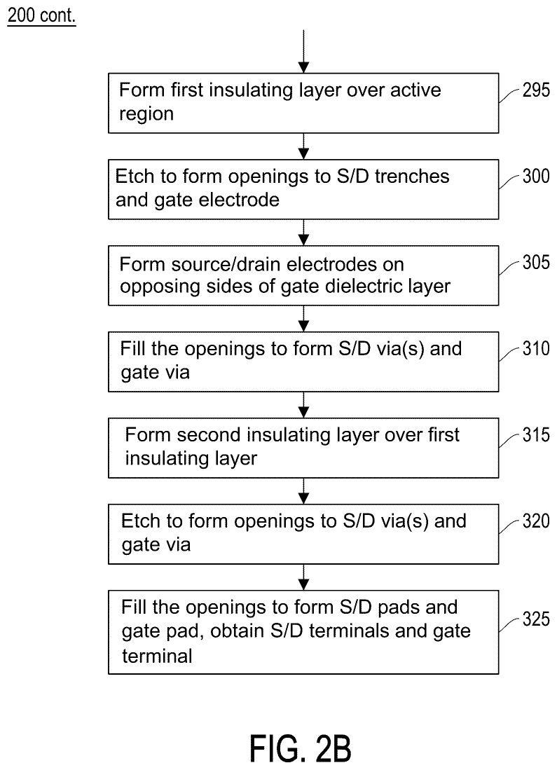

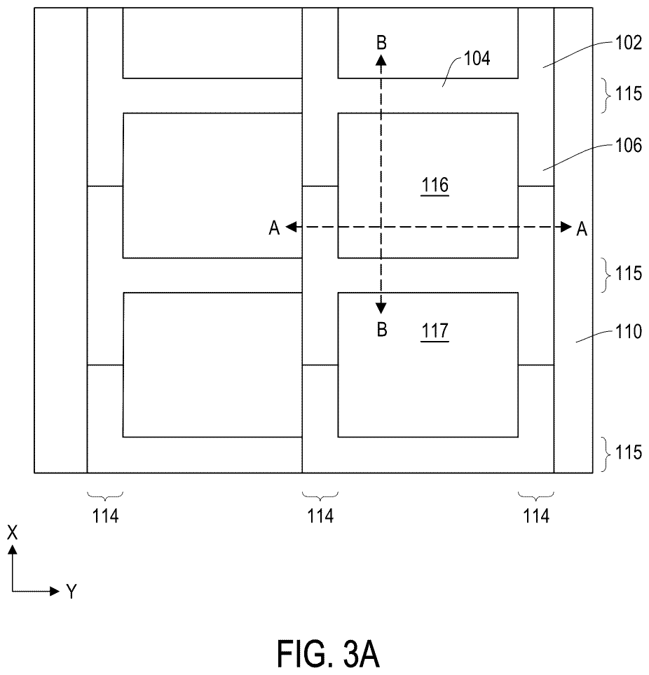

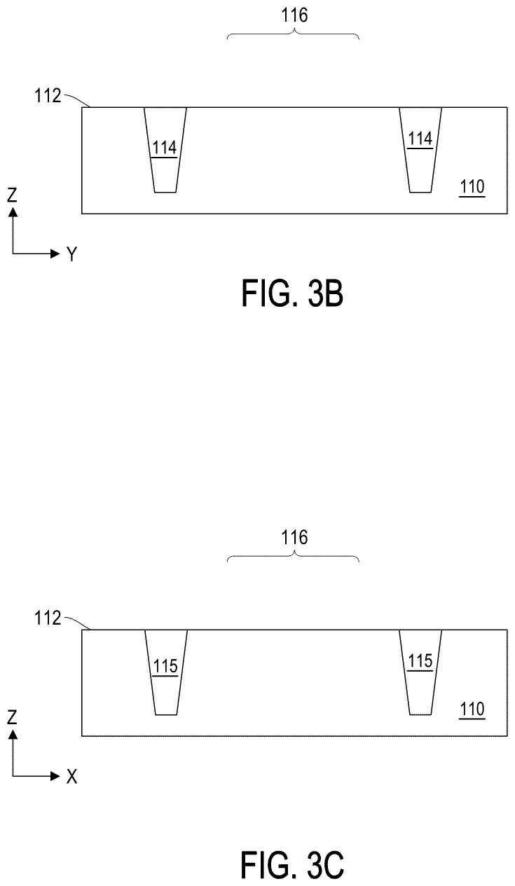

FIG. 2 shows a flow chart illustrating a method 200 for concurrently making transistors in two adjacent active regions, in accordance with some embodiments. Some steps of the method are also illustrated in FIGS. 3A-15B. These figures provide different views for better understanding. While the method steps are discussed below in terms of forming transistors in two active regions, such discussion should also be broadly construed as applying to the concurrent formation of transistors in multiple active regions upon the substrate. It is noted that not all steps described in the flow chart are required.

Initially, FIGS. 3A-3C show the substrate 110 upon which the transistors will be formed. The substrate 110 may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate 110 may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate 110 is silicon. The substrate includes an upper surface 112.

In step 205 of FIG. 2A, and as illustrated in FIGS. 3A-3C, one or more isolation regions are formed in the substrate 110 to define two active regions 116, 117 of the substrate 110. The isolation regions may be, for example, shallow trench isolation (STI) regions or deep trench isolation (DTI) regions. The isolation regions are formed by patterning the substrate, etching one or more isolation trenches in step 210, and filling the trenches with a dielectric material in step 215 to obtain the isolation regions 114, 115. Referring more specifically to FIG. 3A, it should be noted that as illustrated here, the substrate is patterned using an H-shaped mask 102. The mask 102 may be described as including a Y-axis bar 104 and two X-axis legs 106. The mask patterns are overlaid upon each other to obtain the isolation regions 114, 115. This will be explained in more detail further herein.

The dielectric material in the isolation region is commonly silicon dioxide, although other dielectric materials can also be used such as undoped polysilicon, silicon oxide (e.g., SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 112, then recessed back down to the desired height.

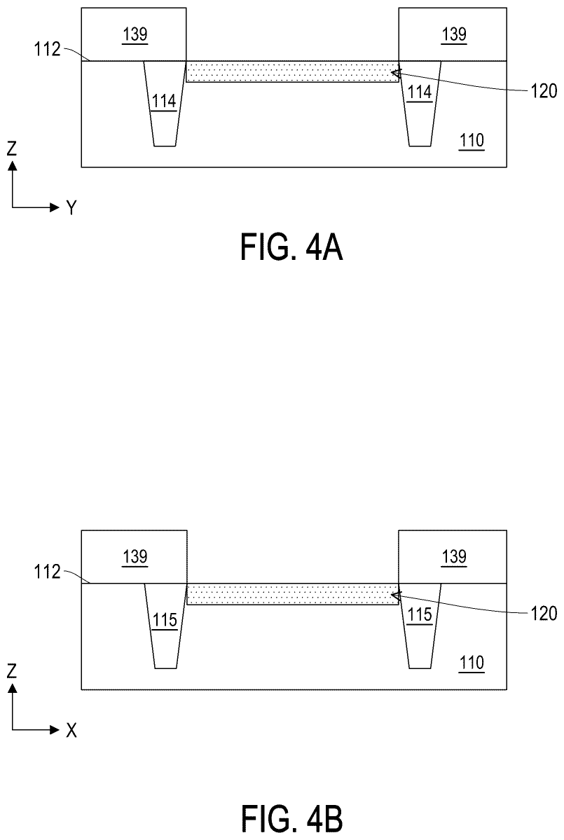

Next, in step 220 of FIG. 2A and as illustrated in FIG. 4A and FIG. 4B, a hard mask 139 is applied to the substrate. The hard mask exposes the two active regions 116, 117. Then, in step 225 of FIG. 2A, a first gate dielectric sublayer 120 is formed upon the substrate 110 between the isolation regions 114 in the first active region 116. In particular embodiments, the first gate dielectric sublayer 120 is formed by thermal oxidation. The exposed surfaces are heated in the presence of oxygen or steam. Alternatively, other suitable processes, such as CVD, PVD, atomic layer deposition (ALD), ion implantation, or other deposition processes may be used to form the first gate dielectric sublayer. The first gate dielectric sublayer may be made, for example, from silicon dioxide, silicon oxynitride (SiOₓN_{y}), SiN, HfO, doped HfO, or other high-k dielectric material.

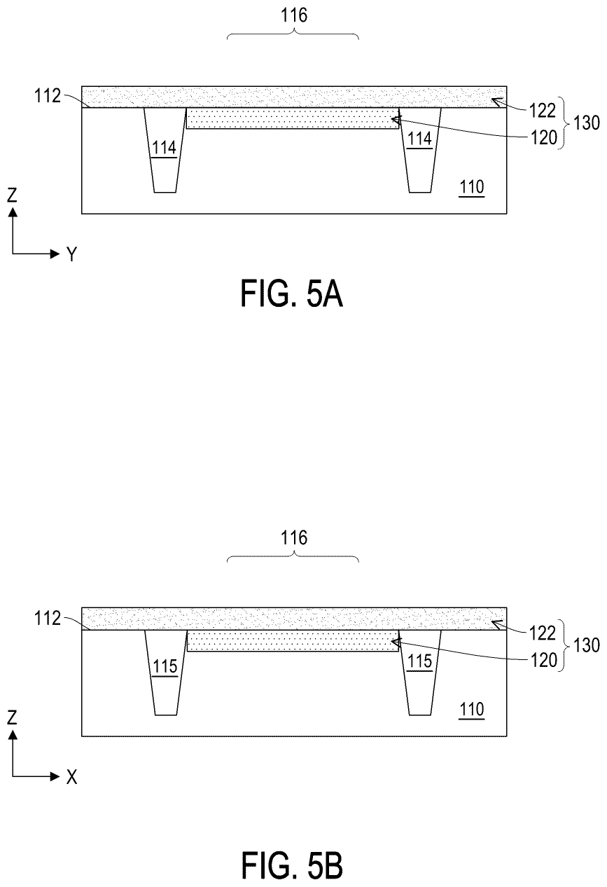

In step 230 of FIG. 2A, the hard mask is then removed. Then, in step 235 and as illustrated in FIG. 5A and FIG. 5B, a second gate dielectric sublayer 122 is formed over the first gate dielectric sublayer 120. A gate dielectric layer 130 is obtained from the combination of the first gate dielectric sublayer 120 and the second gate dielectric sublayer 122. In particular embodiments, CVD is performed upon the substrate to form a high temperature oxide (HTO) layer 122. In particular embodiments, the CVD/high temperature oxidation occurs at a temperature of about 780° C. to about 800° C., although other values and ranges are also within the scope of this disclosure. The CVD is performed using a silicon-containing source gas that acts as a silicon precursor, providing silicon for the reaction. Examples of such silicon precursors include, but are not limited to, tetraethyl orthosilicate (TEOS), silane (SiH₄), trimethylsilane, tetramethylsilane, and hexachlorodisilane (HCDS). Water, oxygen (O₂), or ozone (O₃) can be used to provide oxygen atoms for the reaction. As illustrated here, the second gate dielectric sublayer 122 extends over the isolation regions 114, 115 and the active region 116.

Next, in step 240 of FIG. 2A, the substrate 110 in the second active region is shaped to form fins. Typically, one or more hardmask layers is/are applied to the substrate 110. (The HTO layer 122 may act as a hardmask layer in the second active region.) Mandrels are then formed upon the hardmask layer(s) over the substrate 110. This can be done by depositing a mandrel material layer, forming a photoresist layer upon the mandrel material layer, exposing the photoresist to radiation, and developing the photoresist layer to form a mandrel pattern, and then etching the mandrel material layer to form the mandrels. If desired, the mandrels are then used as a mask, and etching is performed through the hardmask layer(s) and into the substrate is performed to form the fins. Alternatively, in a process known as self-aligned double patterning (SADP), spacers are formed on the sidewalls of the mandrels, and the mandrels are then removed. The spacers are then used as a mask, and etching is performed through the hardmask layer(s) and into the substrate 110 is performed to form the fins. Self-aligned quadruple patterning (SAQP) is a similar process, and can also be used to form the fins. A gate dielectric layer may also be formed upon the fins, for example by thermal oxidation or by deposition.

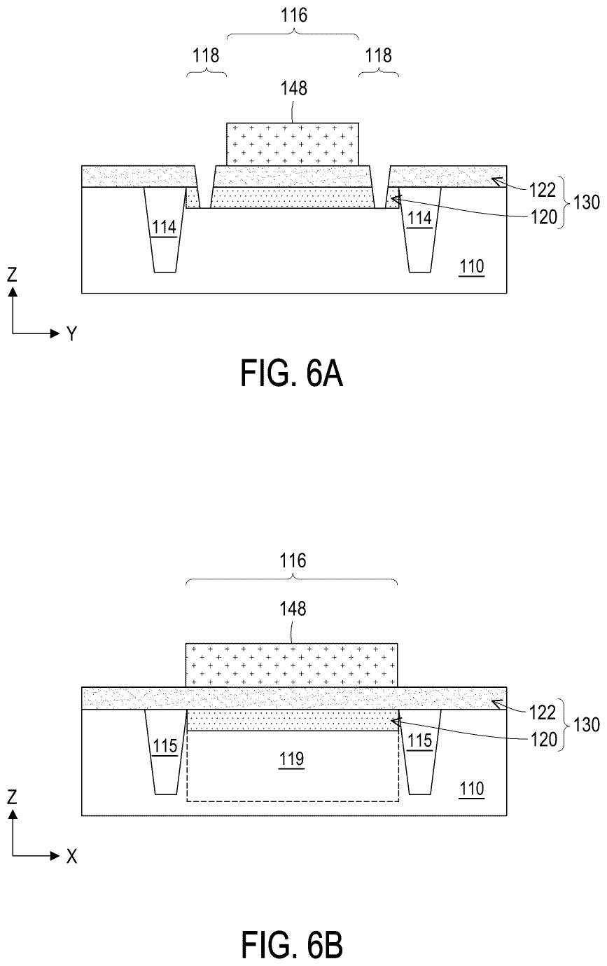

Continuing, in step 245 of FIG. 2A and as illustrated in FIG. 6A and FIG. 6B, trenches 118 are etched through the gate dielectric layer 130 along one axis, on opposite sides of the active region 116. This may be done, for example, by appropriate patterning of a photoresist layer and subsequent etching. Trenches 118 are illustrated as extending along the X-axis and located adjacent the isolation regions 114. Thus, the trenches are seen in FIG. 6A, but not in FIG. 6B. The trenches 118 may also be considered as being within the first active region 116, and are located above the location where the S/D electrodes 160 will be formed.

Then, in step 250 of FIG. 2A, a dummy gate 148 is formed over the gate dielectric layer 130. As seen in FIG. 6A, the dummy gate 148 is located between the trenches 118, and does not fill the trenches. The dummy gate may be formed from any appropriate material, such as polysilicon.

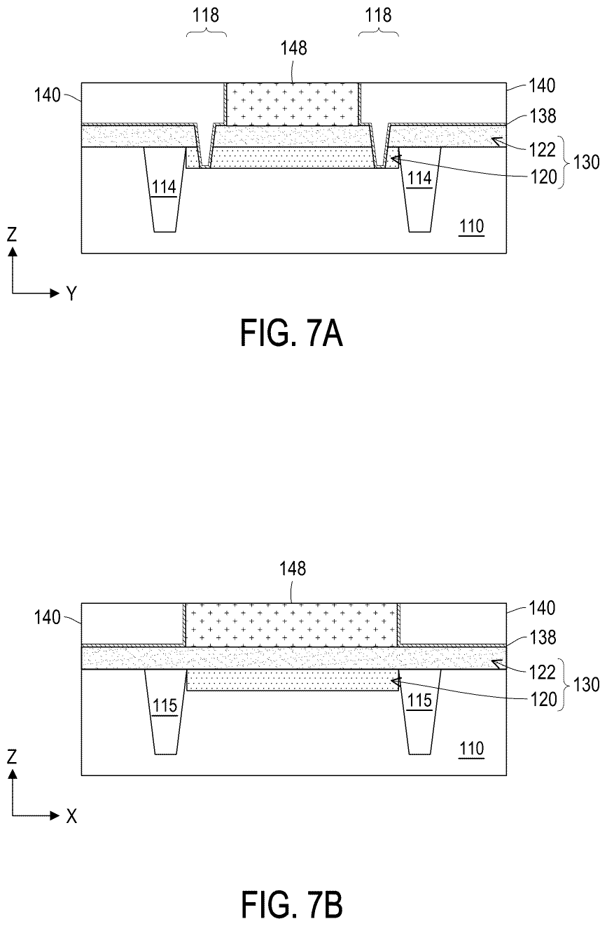

In step 255 of FIG. 2A and as illustrated in FIG. 7A and FIG. 7B, an etch stop layer 138 is formed over the substrate 110. Generally, the etch stop layer is made of a different material from the substrate and the STI regions, and is usually a dielectric material. In some particular embodiments, the etch stop layer can comprise a nitride material, such as silicon nitride (SiN). As best seen in FIG. 7A, the etch stop layer 138 extends up the sides of the dummy gate 148, into the trenches 118, and over the gate dielectric layer 130. Then, in step 260 of FIG. 2A, a first interlayer dielectric (ILD) layer 140 is formed over the substrate 110. As illustrated here, the first ILD layer 140 fills the trenches 118. The first ILD layer is usually a dielectric material that is different from the etch stop layer.

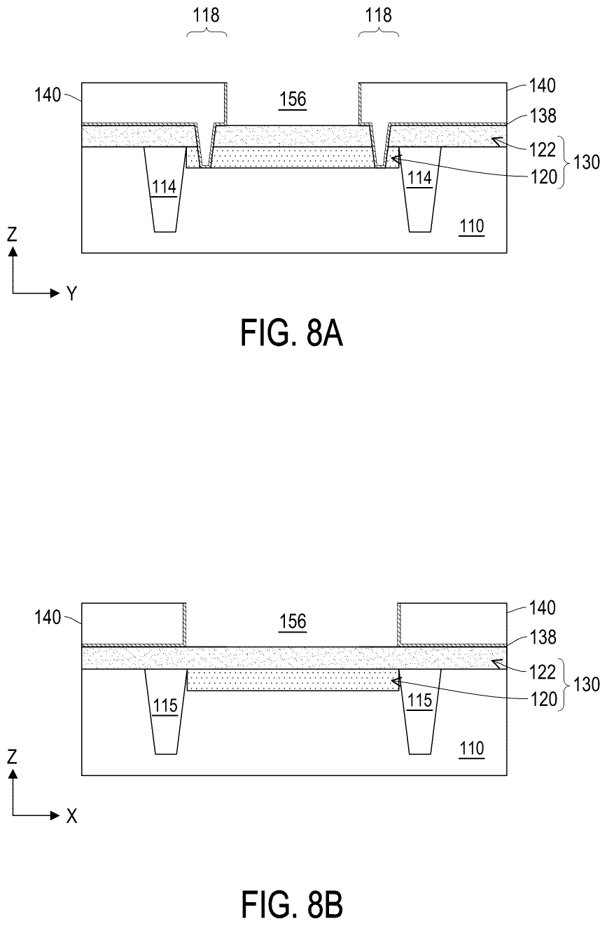

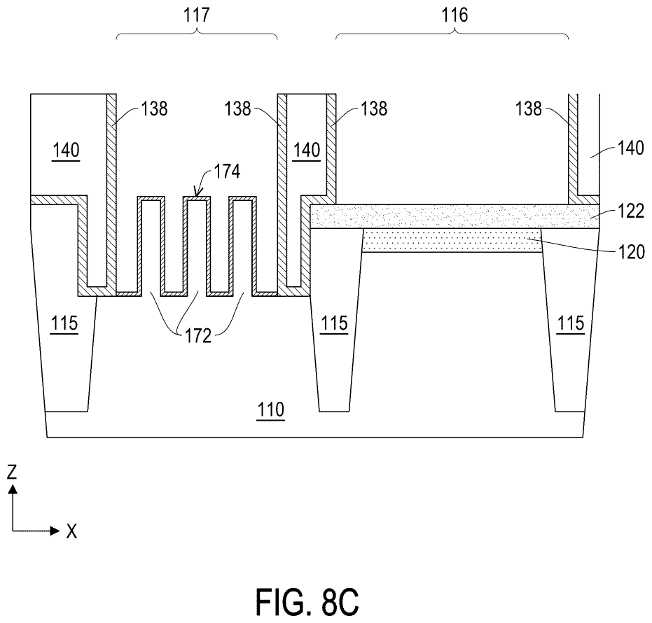

In step 265 of FIG. 2A, and as illustrated in FIGS. 8A-8C, the dummy gate 148 is removed from the substrate 110, leaving a gate volume 156. FIG. 8C shows both the first active region 116 and the second active region 117, which are separated from each other by an isolation region 115. The semiconducting fins 172 are visible with a gate dielectric layer 174 upon them. The second gate dielectric sublayer 122 is not present in the second active region.

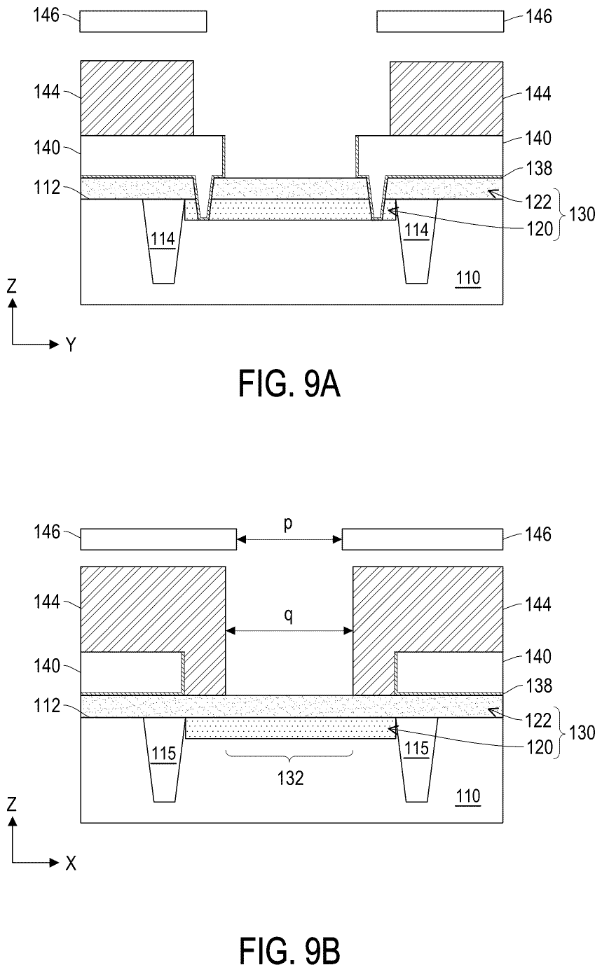

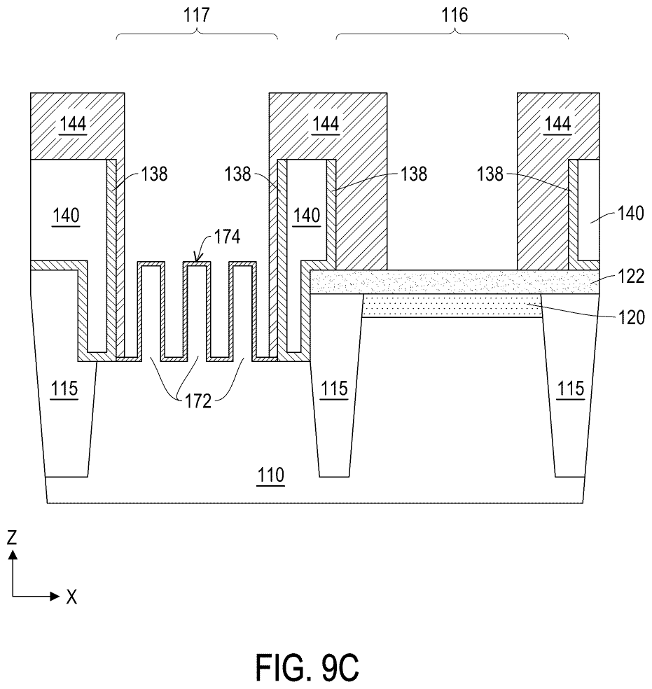

In step 270 of FIG. 2A, and as illustrated in FIGS. 9A-9C, a patterned layer 144 is formed over the substrate 110. This may be, for example, a patterned photoresist (PR) layer. The patterned layer exposes the central region 132 of the second gate dielectric sublayer 122/gate dielectric layer 130.

The mask 146 used to form the pattern in the patterned layer 144 is also illustrated. As indicated in FIG. 9B, the opening in the mask has a length p, and the opening in the patterned layer has a length q, where q>p. This occurs because the radiation does not pass through the opening in the mask in only the vertical direction, but also passes through at angles and thus spreads out. As seen in FIG. 9C, the gate dielectric layer 174 in the second active region 117 can also be exposed, although this is not necessary.

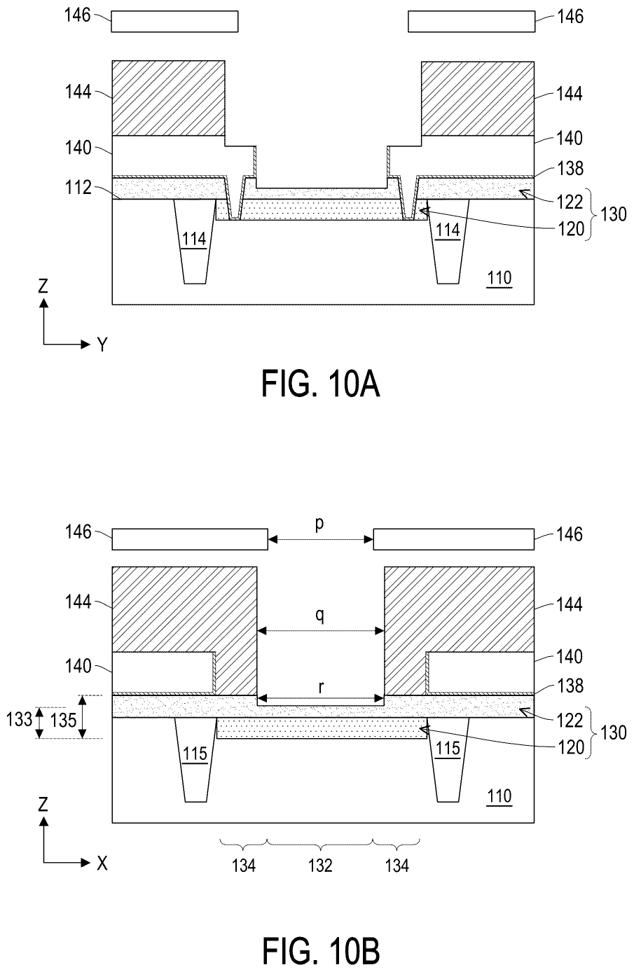

In step 275 of FIG. 2A, and as illustrated in FIG. 10A and FIG. 10B, the exposed central region 132 of the gate dielectric sublayer 130 is thinned, or reduced in thickness. This step may also be described as forming a recess in the central region 132. As a result, the gate dielectric layer 130 comprises a thinned central region 132 and one or more edge regions 134. The second dielectric sublayer 122 is still present in the central region 132, and may not be completely removed. In particular embodiments, this thinning step is performed by a composite etch, using both wet etching and dry etching. As indicated in FIG. 10B, the recess in the central region has a length r, where r>q>p. As illustrated in FIG. 10A, exposed portions of the first ILD layer 140 may undesirably also be etched away in this step.

After this step, the thickness 133 of the thinned central region 132 is less than the thickness 135 of the edge region(s) 134. Put another way, the corner thickness is now greater than the center thickness. In particular embodiments, the difference between the thickness 133 of the thinned central region 132 and the thickness 135 of the edge region(s) 134 is from about 20 angstroms to about 50 angstroms. In some particular embodiments, the thinned central region 132 may have a thickness 133 of about 200 angstroms or lower. Generally, the thickness 133 is a minimum of about 100 angstroms. The edge regions 134 may have a thickness 135 of about 230 angstroms or higher. Generally, the thickness 135 is a maximum of about 300 angstroms. Other values and ranges are also within the scope of this disclosure.

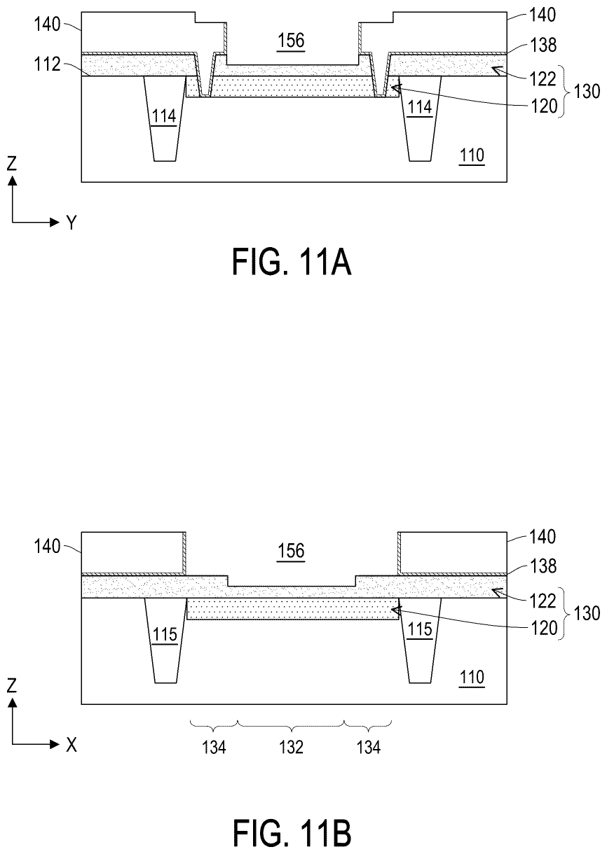

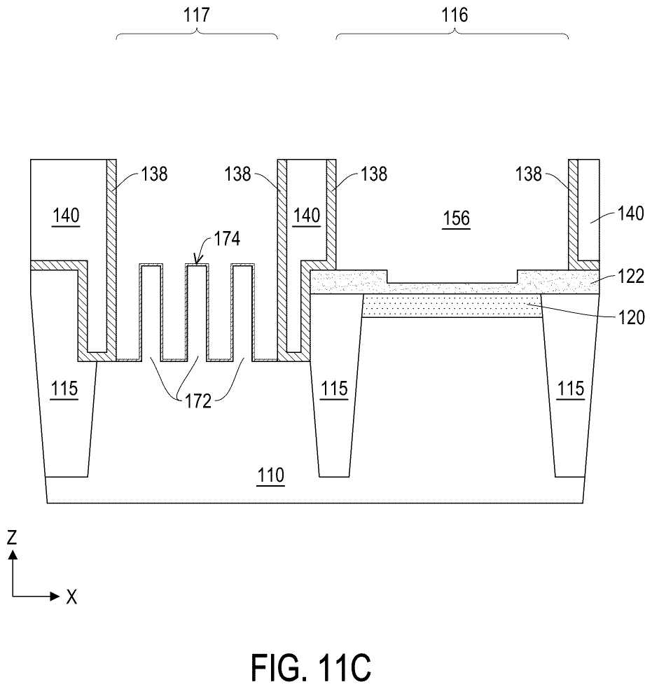

In step 280 of FIG. 2A, and as illustrated in FIGS. 11A-11C, the patterned layer 144 is removed from the substrate 110. As seen in FIG. 11C, the gate dielectric layer 174 in the second active region 117 may also be reduced in thickness. If desired, additional gate oxide layers may then be formed within the gate volume 156 at this time (not illustrated). Such layers may contact the sides of the etch stop layer 138 and the gate dielectric layer 130.

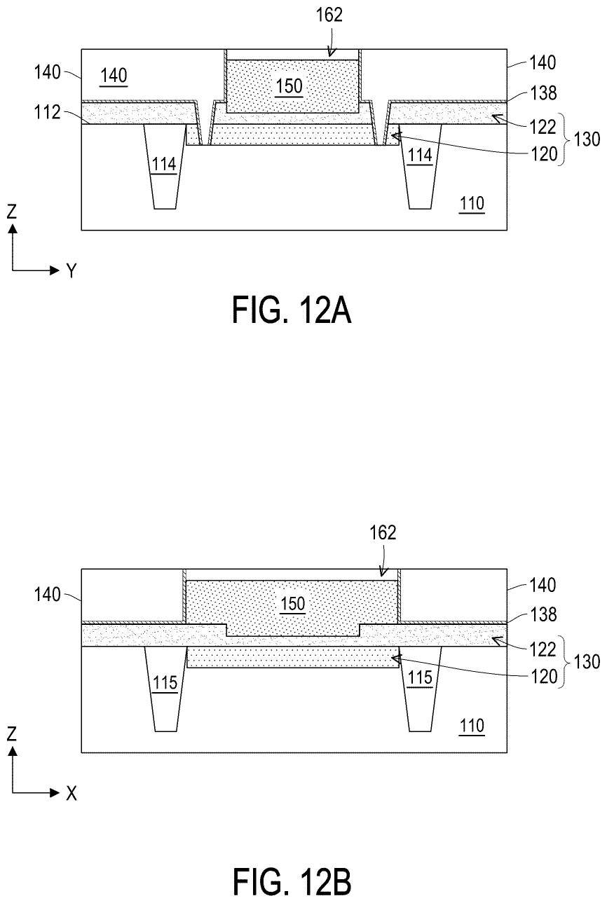

In step 285 of FIG. 2A, and as illustrated in FIG. 12A and FIG. 12B, a gate electrode 150 is formed over the gate dielectric layer 130. In particular embodiments, the gate electrode is formed from a conductive metal. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. The metal may be deposited, for example, via evaporation or sputtering, plating, chemical vapor deposition (CVD), physical vapor deposition (PVD), atomic layer deposition (ALD), or other suitable methods. In step 290 of FIG. 2A, a gate protective layer 162 is formed over the gate electrode. This may be formed from any suitable dielectric material. Planarization, such as CMP, may be performed if desired to remove any material undesirably deposited upon the first ILD layer 140.

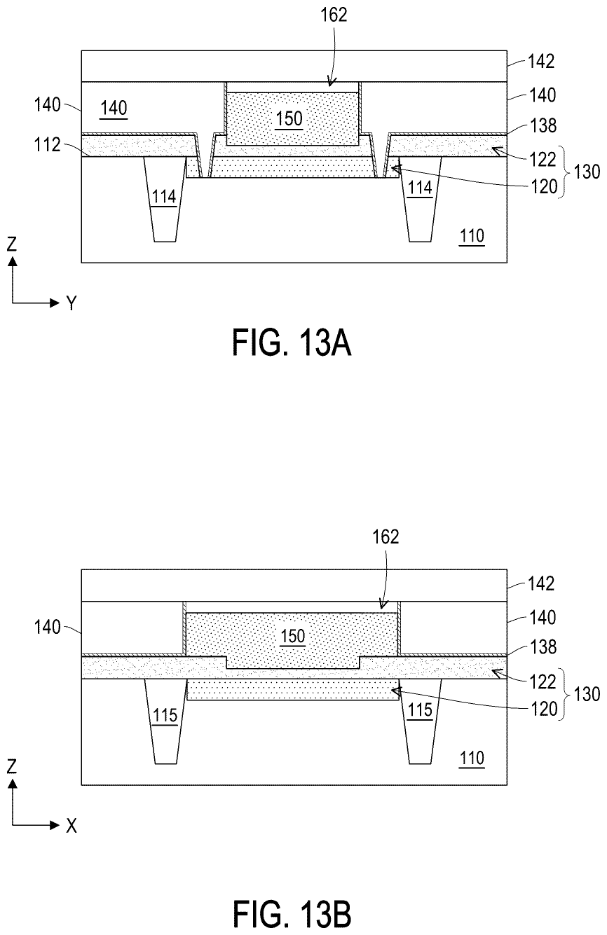

In step 295 of FIG. 2B, and as illustrated in FIG. 13A and FIG. 13B, a second ILD layer or first insulating layer 142 may be formed over the first active region 116. This layer is usually also formed over the second active region 117 as well. This first insulating layer 142 may be formed using processes such as PVD, CVD, SACVD, or other suitable deposition process. The material for the first insulating layer 142 may be silicon or other suitable dielectric material (e.g., silicon dioxide), and may be the same material as that used for the first ILD layer 140.

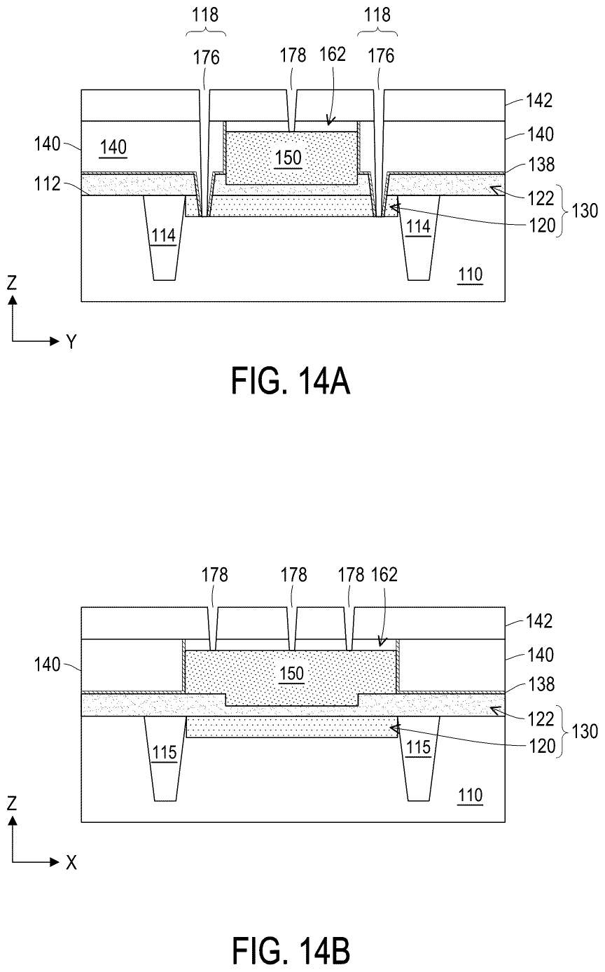

Then, in step 300 of FIG. 2B and as illustrated in FIG. 14A and FIG. 14B, etching is performed to form openings that extend through the first insulating layer 142 and the first ILD layer 140 to the S/D electrodes 160 and the gate electrode 150. This is usually performed in two separate etching steps, with the openings 176 to the S/D electrodes formed separately from the openings 178 to the gate electrode. The S/D openings 176 pass through the trenches 118 to the substrate 110. The portions of the etch stop layer 138 located at the bottom of the trenches is also removed.

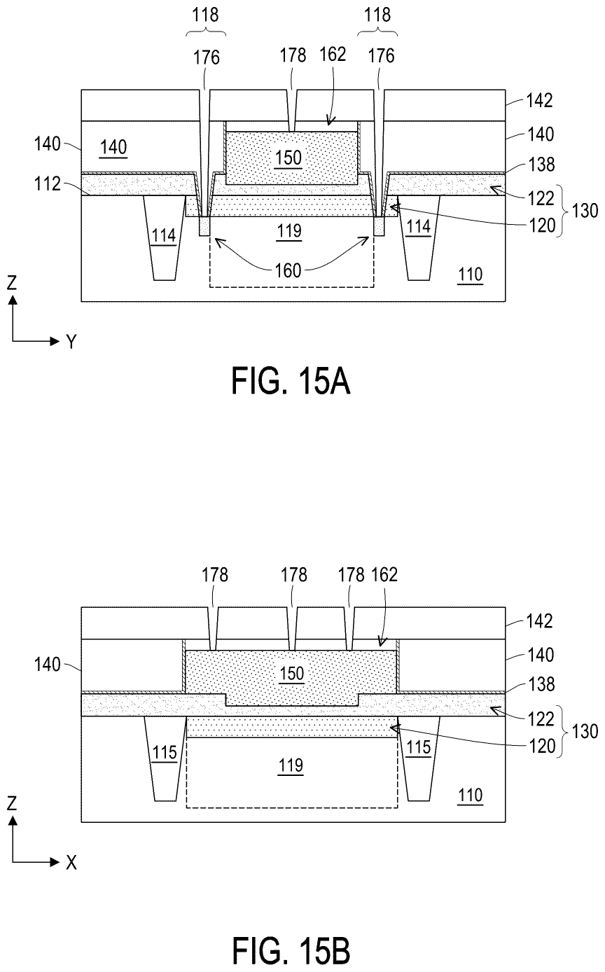

Then, in step 305 of FIG. 2B and as illustrated in FIG. 15A and FIG. 15B, the S/D electrodes 160 are formed on opposite sides of the gate electrode 150. In some embodiments, ions are implanted into the exposed substrate 110 to form the S/D electrodes 160. This may be done using ion implantation or other suitable methods to dope the silicon substrate. Alternatively, patterning and deposition of suitable metals can be performed to form the S/D electrodes. The transistors 101, 103 of FIG. 1D are thus formed.

The depositing of the ions may be performed by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

The S/D electrodes and the substrate are different from each other in their charge. If one is an n-type dopant, then the other is a p-type dopant, or vice versa. As illustrated here, the S/D electrodes are n-type, and the substrate is p-type.

Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In). Different dopants may be used for different substrates.

In step 310 of FIG. 2B, and as illustrated in FIG. 1B and FIG. 1C, the openings are then filled with an electrically conductive material to form source/drain vias 180 and gate via(s) 182. The first insulating layer 142 may also be considered to be an interconnect layer that permits various components to communicate with each other, or a redistribution layer (RDL).

The vias 180, 182 themselves may be sufficient to act as a terminal (i.e., a source terminal, a drain terminal, and a gate terminal) for further processing steps. If a larger contact footprint is desired, these steps can be repeated.

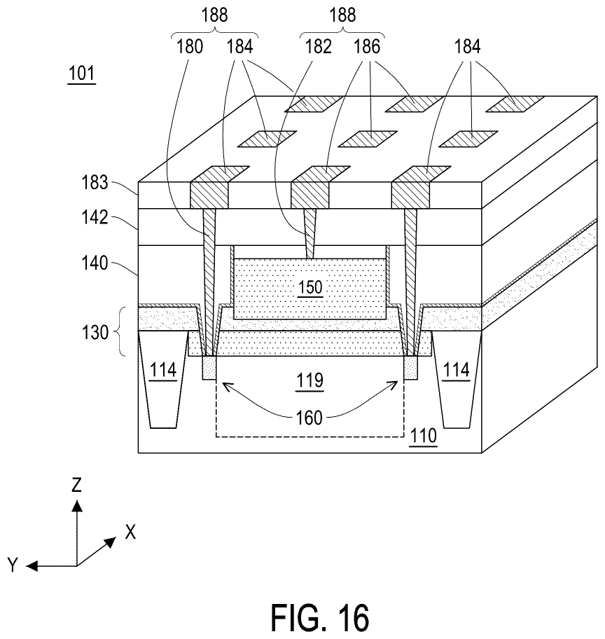

For example, in step 315 of FIG. 2B and as illustrated in FIG. 16, a second insulating layer 183 is formed upon the first insulating layer 142.

The material for the second insulating layer may be the same material as that used for the first insulating layer 142 and/or the first ILD layer 140. Then, in step 320 of FIG. 2B, etching is performed to form openings that extend through the second insulating layer 183 to the vias 180, 182 in the first insulating layer 142. In step 325, the openings are then filled with an electrically conductive material to form source/drain pads 184 and gate pad(s) 186. S/D terminals 188 are formed from the combination of an S/D via 180 and an S/D pad 184. A gate terminal 190 is formed from the combination of a gate via 182 and a gate pad 186. It is noted that the gate terminal 190 can be separated in the direction of the Y-axis from the S/D terminals 188. Nine pads 184, 186 are illustrated here, three pads being used for each electrode (source, drain, and gate), though this is not required.

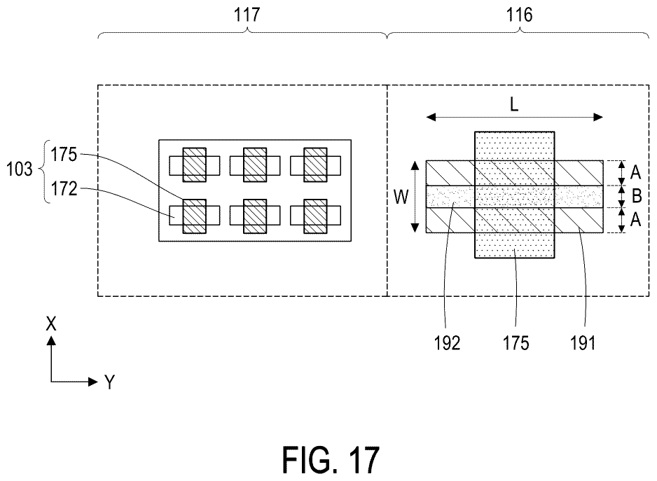

FIG. 17 is a plan view of the substrate 110 showing the first active region 116 and the second active region 117. The second active region is schematically illustrated as containing six FinFETs 103, each having a semiconducting fin 172 and a gate structure 175. The first active region 116 includes a rectangular trench 192 and a gate electrode 150. The trench 192 is formed within a process window 191 having a length L and a width W. As indicated here, the trench 192 has a width B, and A indicates the split on each side, such that the following equation holds: W=B+2A.

FIG. 18 shows a magnified view of a design scheme for forming the rectangular trench 192. The goal is for the trench 192 to have a length L and a width B. The process window 191 within which the trench is formed is shown, again having a length L and a width W. Also shown here is a mask pattern 194 formed in, for example, a photoresist layer 144.

In this regard, due to light scatter, a thin rectangular shape in a mask 146 (see FIGS. 9A-10B) will result in a mask pattern 194 with rounded edges 195, as illustrated here. In this regard, residual photoresist may still remain in open trenches/holes after development. If not removed, this can cause uniformity issues in the subsequent step, such as the thermal oxidation step 230 used to form the first gate dielectric sublayer 120. Photoresist descum is performed to remove the residual photoresist, and typically takes the form of a short plasma etch. However, descum is less effective on rounded edges. As illustrated in FIG. 18, then, the mask pattern 194 is extended so that the rounded edges 195 fall outside the process window 191. As a result, rounded edges are not present in the trench 192 that is formed. Thus, even if residual photoresist remains, it does not effect the designed structure. This design scheme is especially useful when the process window length L or width W is greater than 450 nanometers (nm). In this example, the rounded edges 195 of the trench 192 might be etched away when a perpendicular trench is formed.

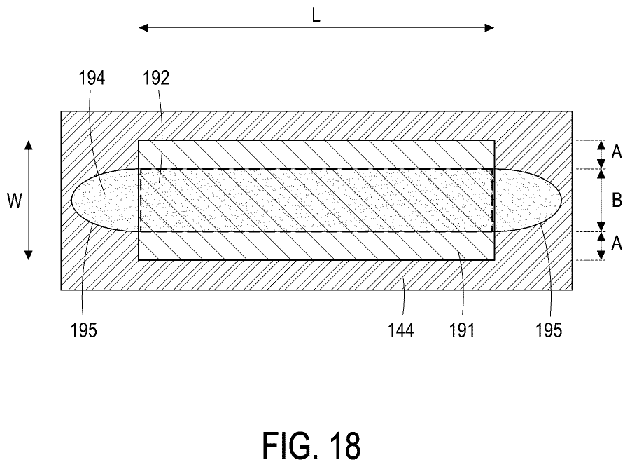

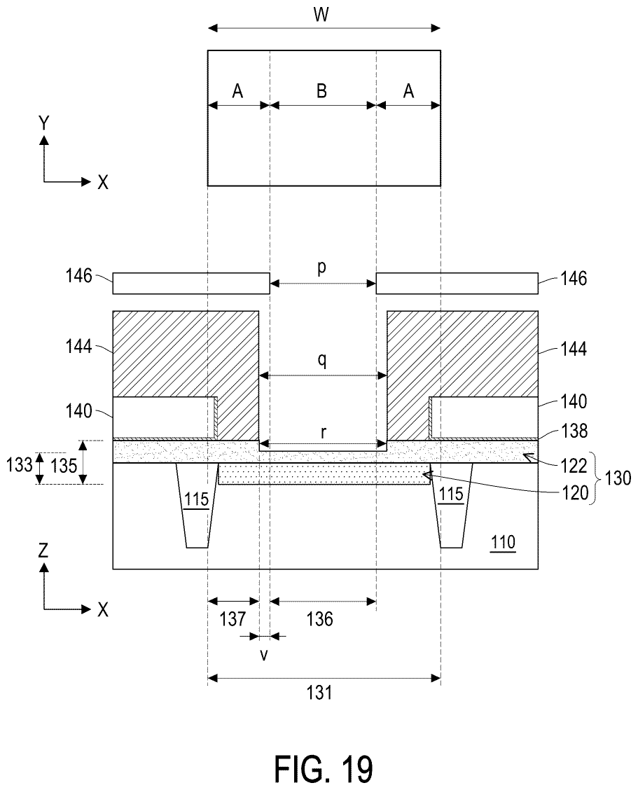

FIG. 19 shows an example plan view and cross-sectional view illustrating the design scheme of FIG. 18 as applied to step 275 of FIG. 2A. It is noted the plan view here is rotated 90°relative to FIG. 18. The cross-sectional view corresponds to that of FIG. 10B.

In this example, the gate dielectric layer 130 has a width 131 of about 450 nm, which is also equivalent to the process window width W (though such equivalence is not required). The central region width 136 and edge region width 137 are indicated here. The desired width 136 of the central region is about 200 nm, which corresponds to the mask opening width p. In this example, due to variations in light scattering and etching, there may be a variance v of, for example, about 65 nm or less. As a result, the value of the central region width 136 could range from about 200 nm to about 330 nm. Similarly, the value of the edge region width 137 could range from about 60 nm to about 125 nm. These values may vary, depending on the process window. However, the central region has the desired width, and any uncontrollable differences in the gate dielectric layer thickness are pushed outside of the relevant area.

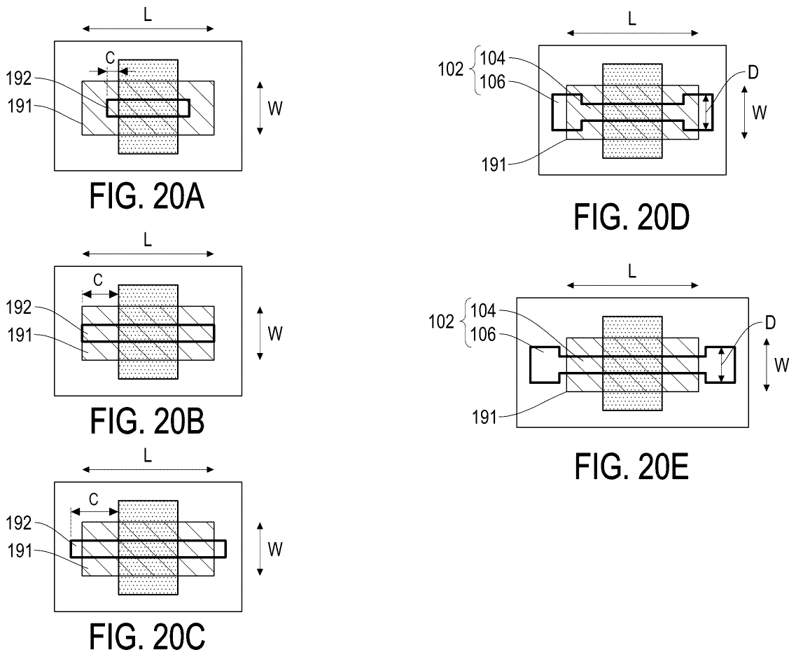

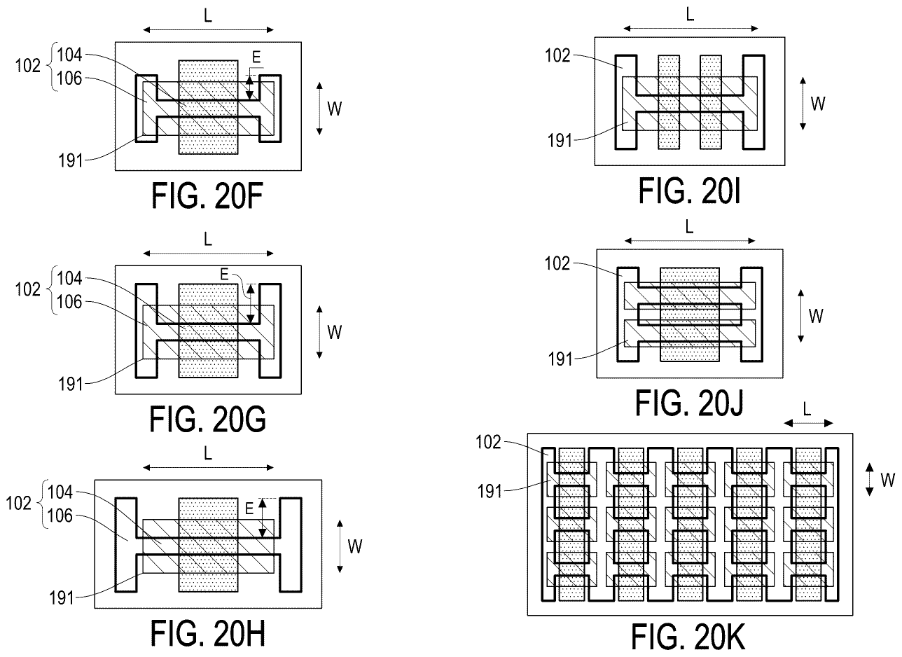

FIGS. 20A-20K show different trench/structure shapes that can be formed using the design scheme of FIG. 18, as well as additional design parameters that can be used. Each of these figures include a process window 191 having a length L and a width W.

In FIGS. 20A-20C, the structure 192 is an extended-space structure, i.e. a rectangular shape. Their lengths vary relative to the process window. The split C is along the length, rather than the width as for split A in FIG. 18.

In FIGS. 20D-20E, the structure 102 is a square-type structure, in which the legs 106 have a square shape rather than a rectangular shape like the bar 104. The location of the legs varies relative to the process window. The width D of the legs is another design parameter that can be considered relative to the width B of the bar.

In FIGS. 20F-20H, the structure 102 is an H-type structure with bar 104 and legs 106. The amount of leg within the process window varies between these figures. The width E of the legs beyond the bar is another design parameter.

FIGS. 20I-20K illustrate special-type structures 102 having different shapes which may require multiple lithography/etch steps because their density is too high to achieve in one pass. The process window 191 for one such lithograph/etch step is shown in each figure, and the various design parameters A, B, C, D, E can be considered in forming these shapes. This can be used for patterns with multiple fingers, a common gate, or arrays.

The transistors and methods of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

The transistors of the present disclosure are especially useful for high voltage, medium voltage, and low voltage devices on chips. High voltage devices typically operate from about 8 volts (V) to about 25V. Medium voltage devices typically operate from about 1.8V to about 8V. Low voltage devices usually operate below 1.8V. In particular embodiments, it is contemplated the FinFET in the second active region 117 is used as a low voltage device, and the planar transistor in the first active region 116 is used as a medium voltage device.

Additional processing steps may be performed to fabricate a semiconductor device or integrated circuit with additional structures. Examples of such steps may include ion implantation, deposition of other materials, etching, etc.

The semiconductor devices might be used in various applications such as BCD (Bipolar-CMOS-DMOS) circuits for driving discrete high voltage components; drivers for LCD, OLED, AMOLED, or QLED display panels, color displays, displays for alternate reality (AR) or virtual reality (VR) applications; image sensors that can be used in systems such as mobile telephones, facial recognition systems, or as motion sensors for automotive applications, security applications, energy efficiency, etc. ; power management devices that control the flow and direction of electrical power or battery protectors or power supplies; and/or image signal processors (ISP).

The methods and systems of the present disclosure have several advantages. The design scheme and mask patterns can increase the thickness on the corners of the gate dielectric layer without needing new masks. Different split designs are available for different active region widths to cover the entire photolithography process window. The designs also reduce problems caused by photoresist descum, rounding and peeling, and enlarge the process window. In addition, integrated processes for both planar transistors and FinFETs typically have a worse process window and suffer a large after-development inspection (ADI) bias for non-correctable errors (NCE). Such issues are addressed in the present disclosure.

Some embodiments of the present disclosure thus relate to methods for forming a transistor. One or more isolation regions are formed in a substrate on opposite sides of a first active region. A first gate dielectric sublayer is formed between the isolation regions in the first active region. A second gate dielectric sublayer is formed over the first gate dielectric sublayer and the isolation regions to form a gate dielectric layer. A dummy gate is formed over the gate dielectric layer. An etch stop layer is formed over the substrate. A first interlayer dielectric (ILD) layer is formed over the substrate. The dummy gate is removed. A patterned layer is formed over the substrate that exposes a central region of the second gate dielectric sublayer. The exposed central region of the second gate dielectric sublayer is then thinned (i.e. reduced in thickness), so that the gate dielectric layer comprises a thinned central region and one or more edge regions. A gate electrode is then formed over the gate dielectric layer. Source/drain (S/D) electrodes are formed on opposite sides of the gate dielectric layer in the first active region.

Also disclosed in various embodiments are transistors that comprise a substrate with one or more active regions extending between two S/D electrodes. Isolation regions are present on opposite sides of the active region. A gate dielectric layer runs over the one or more active regions between the two S/D electrodes; and a gate electrode is located over the gate dielectric layer. The gate dielectric layer comprises a central region and one or more edge regions. A thickness of the central region is less than a thickness of the plurality of edge regions. Alternatively, the gate electrode can be described as comprising a central region and one or more edge regions disposed on opposing sides of the central region, with the central region being thicker than the plurality of edge regions.

Also disclosed are semiconductor devices comprising one or more transistors having the structures described above. The transistor(s) may be packaged, for example with ILD regions and insulating layer(s) as described above, with vias/terminals extending through the insulating layer(s).

Also disclosed are methods for operating a transistor. A voltage signal to a gate electrode is changed to open a channel between two source/drain electrodes. The transistor has the structures described above.

The methods, systems, and devices of the present disclosure are further illustrated in the following non-limiting working example, it being understood that they are intended to be illustrative only and that the disclosure is not intended to be limited to the materials, conditions, process parameters and the like recited herein.

### EXAMPLE

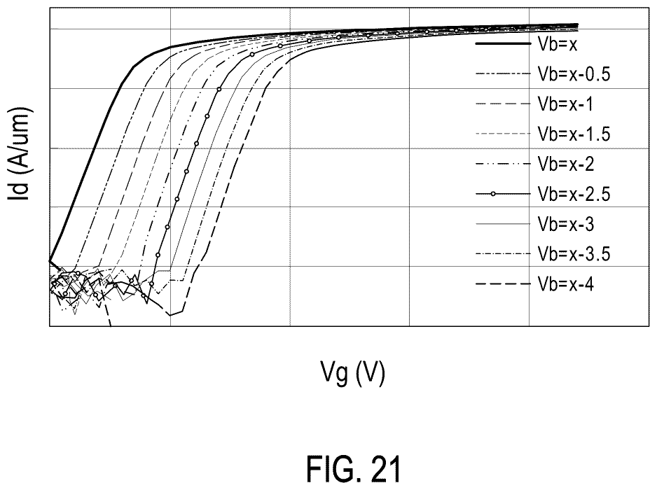

An NMOS transistor having the structure of FIGS. 1A-1C was made. The thickness 133 of the central region was 200 angstroms, and the thickness 135 of the edge regions was 240 angstroms. FIG. 21 is a graph of current vs voltage for the transistor at various bias voltages (Vb). No double hump is seen.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a transistor, the method comprising:
forming isolation regions in a substrate on opposite sides of a first active region;
forming a first gate dielectric sublayer between the isolation regions in the first active region;
forming a second gate dielectric sublayer over the first gate dielectric sublayer and the isolation regions to form a gate dielectric layer;
forming a dummy gate over the gate dielectric layer;
forming an etch stop layer over the substrate;
forming a first interlayer dielectric (ILD) layer over the substrate;
removing the dummy gate;
forming a patterned layer over the substrate that exposes a central region of the second gate dielectric sublayer;
thinning the exposed central region of the second gate dielectric sublayer, so that the gate dielectric layer comprises a thinned central region and one or more edge regions;
forming a gate electrode over the gate dielectric layer; and
forming source/drain (S/D) electrodes on opposite sides of the gate dielectric layer in the first active region.

2. The method of claim 1, wherein a difference in a thickness of the gate dielectric layer central region and a thickness of the gate dielectric layer edge regions is from about 20 angstroms to about 50 angstroms.

3. The method of claim 1, wherein the gate dielectric layer central region has a thickness of about 200 angstroms or lower.

4. The method of claim 1, wherein the gate dielectric layer edge regions have a thickness of about 230 angstroms or higher.

5. The method of claim 1, wherein the first gate dielectric sublayer is formed by thermal oxidation.

6. The method of claim 1, wherein the second gate dielectric sublayer is formed by high temperature oxidation.

7. The method of claim 1, further comprising etching the gate dielectric layer between the isolation regions down to the substrate to form trenches, wherein the first ILD layer fills the trenches.

8. The method of claim 7, wherein the source/drain (S/D) electrodes are formed by:
etching through the first ILD layer, the etch stop layer, and the gate dielectric layer down to the substrate; and
implanting ions into the substrate to form the S/D electrodes.

9. The method of claim 1, wherein one of the isolation regions separates the first active region from a second active region, and the method further comprises:
forming fins in the second active region.

10. The method of claim 1, further comprising:
forming a first insulating layer over the substrate;
etching openings through the first insulating layer to the S/D electrodes and the gate electrode; and
filling the openings with an electrically conductive material to form at least one source via, at least one drain via, and at least one gate via.

11. The method of claim 10, further comprising:
forming a second insulating layer over the first insulating layer;
etching the second insulating layer to form pads over the at least one source via, at least one drain via, and at least one gate via; and
filling the pads with an electrically conductive material to form a source terminal, a drain terminal, and a gate terminal.

12. A transistor, comprising:
a substrate with one or more active regions extending between two S/D electrodes;
isolation regions on opposite sides of the active region;
a gate dielectric layer within the one or more active regions between the two S/D electrodes; and
a gate electrode over the gate dielectric layer;
wherein the gate dielectric layer comprises a central region and one or more edge regions, and a thickness of the central region is less than a thickness of the plurality of edge regions.

13. The transistor of claim 12, wherein the transistor is a planar transistor.

14. The transistor of claim 12, wherein a difference in a thickness of the gate dielectric layer central region and a thickness of the gate dielectric layer edge regions is from about 20 angstroms to about 50 angstroms.

15. The transistor of claim 12, wherein the gate dielectric layer central region has a thickness of about 200 angstroms or lower.

16. The transistor of claim 12, wherein the gate dielectric layer edge regions have a thickness of about 230 angstroms or higher.

17. A method for operating a transistor, comprising:
changing a voltage signal to a gate electrode to open a channel between two source/drain electrodes;
wherein the gate electrode comprises a central region and one or more edge regions disposed on opposing sides of the central region, and the central region is thicker than the plurality of edge regions.

18. The method of claim 17, wherein the transistor is a planar transistor.

19. The transistor of claim 12, wherein a difference in a thickness of the gate dielectric layer central region and a thickness of the gate dielectric layer edge regions is from about 20 angstroms to about 50 angstroms.

20. The transistor of claim 12, wherein the gate dielectric layer central region has a thickness of about 200 angstroms or lower, and the gate dielectric layer edge regions have a thickness of about 230 angstroms or higher.
